(19) United States
(12) Patent Application Publication
(10) Pub. No.: US 2025/0299998 A1
(43) Pub. Date: Sep. 25, 2025

(54) SHEET PROCESSING METHOD, CHIP MANUFACTURING METHOD, AND SUBSTRATE MANUFACTURING METHOD

(71) Applicant: DISCO CORORATION, Tokyo (JP)

(72) Inventor: Yoshinobu SAITO, Tokyo (JP)

(21) Appl. No.: 19/073,213

(22) Filed: Mar. 7, 2025

(30) Foreign Application Priority Data
Mar. 21, 2024 (JP) 2024-044382
Dec. 9, 2024 (JP) 2024-214410

(51) Int. Cl. H01L 21/683; H01L 21/78

(52) U.S. Cl. CPC H01L 21/6836; H01L 21/78

(57) ABSTRACT

A sheet processing method for processing a sheet fixed to a target object includes preparing the target object to which the sheet is fixed, bringing a light absorbing member configured to generate heat by absorbing light into contact with an unfixed region not fixed to the target object in the sheet, and heating and shrinking the unfixed region by making the light absorbing member generate heat through irradiation of the light absorbing member with the light.

### BACKGROUND OF THE INVENTION

### Field of the Invention

The present invention relates to a sheet processing method for processing a sheet fixed to a target object, a chip manufacturing method for manufacturing chips by dividing a target object to which a sheet is fixed, and a substrate manufacturing method for manufacturing a substrate by processing a target object to which a sheet is fixed.

### Description of the Related Art

A device chip manufacturing process uses a wafer having, on a top surface side thereof, a device region in which a plurality of devices are formed. The device region is demarcated into a plurality of regions by planned dividing lines (streets) set in a lattice manner. A device is formed in each of the plurality of regions. Device chips including the devices are obtained by dividing the wafer into individual pieces along the planned dividing lines. The device chips are incorporated in various electronic apparatuses such as mobile telephones or personal computers.

A cutting apparatus that cuts the wafer by an annular cutting blade is used to divide the wafer. In addition, recently, the development of a process of dividing the wafer by laser processing has been underway. For example, modified layers that function as a division starting point are formed within the wafer along the planned dividing lines by irradiating the wafer with a laser beam. Thereafter, an external force is applied to the wafer by stretching and expanding a sheet (holding tape) fixed to the wafer. As a result, the wafer is ruptured with the modified layers as a starting point, and is divided along the planned dividing lines (see Japanese Patent Laid-Open No. 2007-173475).

In addition, recently, thinning of the device chips has been demanded as electronic apparatuses have been miniaturized. Accordingly, processing that grinds and thins the wafer before being divided may be performed. However, when the whole of the wafer is thinned, the rigidity of the wafer is decreased, and consequently the wafer tends to be deformed or damaged. It is therefore difficult to treat the wafer after being thinned. Accordingly, a processing method referred to as TAIKO grinding has been proposed which grinds and thins only a central portion coinciding with the device region on the undersurface side of the wafer. When the TAIKO grinding is performed, a recessed portion is formed in the central portion of the wafer, but an outer circumferential portion of the wafer is maintained in a thick state without being thinned. As a result, the outer circumferential portion of the wafer functions as an annular reinforcing portion to suppress a decrease in the rigidity of the wafer after being ground (see Japanese Patent Laid-Open No. 2007-19461).

### SUMMARY OF THE INVENTION

When a target object such as the wafer is to be subjected to processing such as division or grinding, the target object is supported by an annular frame for the convenience of handling (transporting, holding, and the like) of the target object. Specifically, a circular opening portion is provided in a central portion of the frame, and the target object is disposed inside the frame. Then, a sheet (film) such as an adhesive tape is fixed to the target object and the frame so as to cover the opening portion. The target object is thereby supported by the frame via the sheet.

However, slack may occur in the sheet when the target object is subjected to predetermined processing in a state in which the sheet is fixed to the target object. For example, when the process of dividing the wafer by applying an external force to the wafer through expansion of the sheet as described earlier is performed, the sheet remains stretched after the division of the wafer, and thus slack occurs in the sheet. In addition, after the wafer is divided into a plurality of chips, processing of widening intervals between the device chips by expanding the sheet fixed to the wafer may be performed in order to prevent collision between the chips from occurring easily. Also in this case, slack similarly occurs in the sheet. Further, when the wafer resulting from the TAIKO grinding described above is to be processed, the sheet is fixed so as to be pressed against the recessed portion formed on the undersurface side of the wafer. Then, after the wafer is subjected to various kinds of processing, the outer circumferential portion (reinforcing portion) is finally separated and removed from the wafer. At this time, the tension of the sheet fixed to the recessed portion of the wafer is released, and slack may occur in the sheet.

When slack occurs in the sheet, an inconvenience occurs in subsequent handling of the target object. For example, the slack in the sheet causes the target object to be in a state of hanging down from the frame, and thus it may be difficult to house the target object in a predetermined housing container (cassette). In addition, when the target object in a state of being divided into a plurality of chips is supported and transported by the slackened sheet, chips may collide with each other due to swaying of the target object, and thereby the chips may be damaged.

Accordingly, when slack has occurred in the sheet due to the processing of the target object, processing of heating and shrinking (contracting) a region in which the slack in the sheet has occurred (slackened region) may be performed. Specifically, the slackened region of the sheet is irradiated with light such as a laser beam, and the slackened region is heated by absorbing the light. Consequently, the slackened region is shrunk, so that the slack in the sheet is removed.

However, the material of the sheet fixed to the target object differs depending on the kind of the target object, the contents of the processing performed on the target object, and the like. Moreover, in a case of removing the slack in the sheet by irradiating the sheet with the light, the wavelength of the light needs to be set according to the material of the sheet so that the light is absorbed by the sheet with high efficiency. Therefore, the process of removing the slack in the sheet by the irradiation with the light takes labor, and depending on the material of the sheet, the absorption itself of the light with high efficiency may be difficult. In addition, equipment that can irradiate the sheet with light of various wavelengths needs to be prepared, which causes increases in complexity and cost of the equipment.

The present invention has been made in view of such problems. It is an object of the present invention to provide a sheet processing method, a chip manufacturing method, and a substrate manufacturing method that can easily suppress slack in a sheet fixed to a target object.

In accordance with an aspect of the present invention, there is provided a sheet processing method for processing a sheet fixed to a target object, the sheet processing method including preparing the target object to which the sheet is fixed, bringing a light absorbing member configured to generate heat by absorbing light into contact with an unfixed region not fixed to the target object in the sheet, and heating and shrinking the unfixed region by making the light absorbing member generate heat through irradiation of the light absorbing member with the light.

Incidentally, preferably, the sheet is fixed to an annular frame having an opening portion in which the target object can be disposed, and the unfixed region is an annular region exposed between the target object and the frame. In addition, preferably, the target object is processed, and the unfixed region in which slack occurs due to the processing of the target object is shrunk.

In addition, preferably, the processing of the target object is processing that, after forming division starting points in the target object along a planned dividing line, divides the target object along the planned dividing line by expanding the sheet. In addition, preferably, a frame unit is prepared which includes the target object having a recessed portion provided in a central portion of the target object and having an annular reinforcing portion provided in an outer circumferential portion of the target object, the reinforcing portion surrounding the recessed portion, and the sheet fixed to the recessed portion and the reinforcing portion of the target object, and the processing of the target object is processing that separates the reinforcing portion from the target object.

In accordance with another aspect of the present invention, there is provided a chip manufacturing method for manufacturing chips by dividing a target object to which a sheet is fixed, the chip manufacturing method including preparing the target object to which the sheet is fixed, after forming division starting points in the target object along a planned dividing line, dividing the target object into a plurality of the chips along the planned dividing line by expanding the sheet, bringing a light absorbing member configured to generate heat by absorbing light into contact with an unfixed region not fixed to the target object in the sheet, and heating and shrinking the unfixed region by making the light absorbing member generate heat through irradiation of the light absorbing member with the light.

In accordance with a further aspect of the present invention, there is provided a chip manufacturing method for manufacturing chips by dividing a target object to which a sheet is fixed, the chip manufacturing method including preparing the target object to which the sheet is fixed, after dividing the target object into a plurality of the chips along a planned dividing line, widening intervals between the plurality of chips by expanding the sheet, bringing a light absorbing member configured to generate heat by absorbing light into contact with an unfixed region not fixed to the target object in the sheet, and heating and shrinking the unfixed region by making the light absorbing member generate heat through irradiation of the light absorbing member with the light.

In accordance with a still further aspect of the present invention, there is provided a substrate manufacturing method for manufacturing a substrate by processing a target object to which a sheet is fixed, the substrate manufacturing method including preparing the target object having a recessed portion provided in a central portion of the target object and having an annular reinforcing portion provided in an outer circumferential portion of the target object, the reinforcing portion surrounding the recessed portion, the sheet being fixed to the recessed portion and the reinforcing portion, manufacturing the substrate by separating the reinforcing portion from the target object, bringing a light absorbing member configured to generate heat by absorbing light into contact with an unfixed region not fixed to the target object in the sheet, and heating and shrinking the unfixed region by making the light absorbing member generate heat through irradiation of the light absorbing member with the light.

The sheet processing method, the chip manufacturing method, and the substrate manufacturing method according to one aspect of the present invention heat and shrink the unfixed region of the sheet by making the light absorbing member in contact with the unfixed region generate heat through irradiation of the light absorbing member with the light. This obviates a need for work of setting the irradiation conditions of the light minutely according to the material of the sheet, and thus simplifies the processing of suppressing slack in the sheet.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a flowchart illustrating a sheet processing method;

FIG. 2 is a perspective view illustrating a target object, a frame, and a sheet;

FIG. 3 is a perspective view illustrating a frame unit;

FIG. 4 is a partially sectional front view illustrating a laser processing apparatus;

FIG. 5A is a partially sectional front view illustrating an expanding apparatus;

FIG. 5B is a partially sectional front view illustrating the expanding apparatus that expands the sheet;

FIG. 6 is a partially sectional front view illustrating the expanding apparatus in a light absorbing member disposing step and a shrinking step;

FIG. 7A is a perspective view illustrating a modification of the target object;

FIG. 7B is a sectional view illustrating a modification of the frame unit;

FIG. 8A is a partially sectional front view illustrating a laser processing apparatus;

FIG. 8B is a sectional view illustrating a part of the target object in which a modified region is formed;

FIG. 9A is a partially sectional front view illustrating a separating apparatus at a time of applying an external force to the target object;

FIG. 9B is a partially sectional front view illustrating the separating apparatus at a time of separating a reinforcing portion from the target object;

FIG. 10 is a partially sectional front view illustrating the separating apparatus in the light absorbing member disposing step and the shrinking step;

FIG. 11A is a sectional view illustrating the target object to be divided by cutting processing; and

FIG. 11B is a sectional view illustrating the target object to be divided by laser processing.

### DETAILED DESCRIPTION OF THE PREFERRED EMBODIMENTS

### First Embodiment

An embodiment according to one aspect of the present invention will hereinafter be described with reference to the accompanying drawings. In the present embodiment, a description will be made of a concrete example of a sheet processing method (film processing method) according to the one aspect of the present invention.

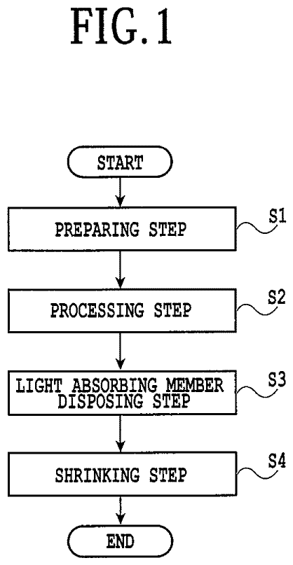

FIG. 1 is a flowchart illustrating the sheet processing method. In the present embodiment, a preparing step S1 is performed which prepares a target object to which a sheet is fixed, and thereafter a processing step S2 is performed which performs predetermined processing on the target object. Then, a light absorbing member disposing step S3 and a shrinking step S4 are performed. Slack occurring in the sheet in the processing step S2 is thereby reduced or removed.

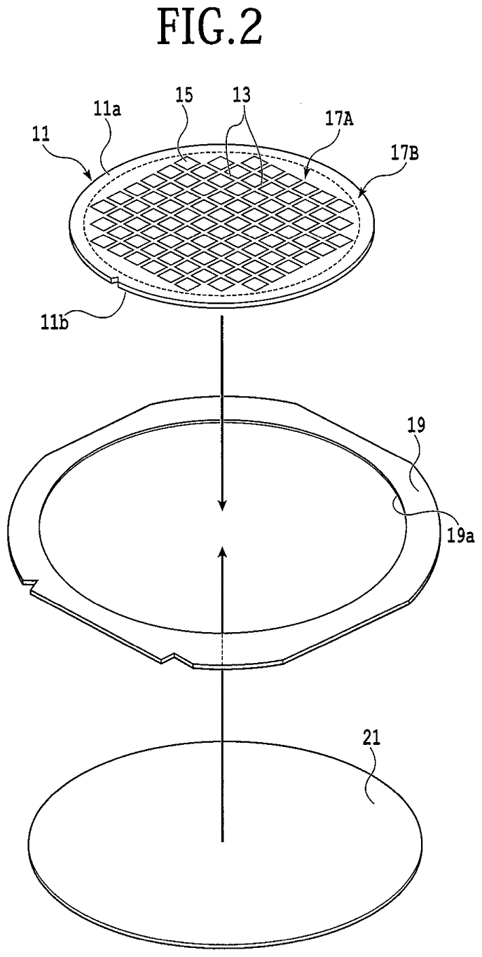

FIG. 2 is a perspective view illustrating a target object 11, a frame 19, and a sheet (film) 21. The target object 11 is a member to which the sheet 21 is fixed. The target object 11 corresponds to a processing target object (a workpiece, a cleaning target object, an inspection target object, or the like) that is subjected to various kinds of processing by processing apparatuses such as a processing apparatus, a cleaning apparatus, and an inspecting apparatus.

For example, the target object 11 is a disk-shaped wafer formed of a semiconductor material such as single crystal silicon, and has a top surface (first surface) 11a and an undersurface (second surface) 11b that are substantially parallel with each other. In addition, the target object 11 is demarcated into a plurality of rectangular regions by a plurality of planned dividing lines (streets) 13 arranged in a lattice manner so as to intersect one another. A device 15 such as an integrated circuit (IC), a large scale integration (LSI) circuit, a light emitting diode (LED), or a microelectromechanical system (MEMS) device is formed on the top surface 11a side of each of the plurality of regions demarcated by the planned dividing lines 13.

The target object 11 includes, on the top surface 11a side, a substantially circular device region 17A having a plurality of devices 15 formed therein and an annular peripheral surplus region 17B that surrounds the device region 17A. The peripheral surplus region 17B corresponds to a band-shaped region having a predetermined width (for example, approximately 2 mm), the band-shaped region including an outer circumferential edge of the top surface 11a. In the peripheral surplus region 17B, no devices 15 are formed, or only devices (dummy devices) not used as products are formed. Incidentally, in FIG. 1, an imaginary boundary between the device region 17A and the peripheral surplus region 17B is represented by a broken line.

In the present embodiment, a description will be made of a case of performing division processing that divides the target object 11 along the planned dividing lines 13. That is, the target object 11 is a workpiece that is subjected to the division processing. A plurality of chips (device chips) respectively having the devices 15 are obtained by dividing the target object 11 along the planned dividing lines 13.

However, there are no limitations on the kind, material, shape, structure, size, and the like of the target object 11. For example, the target object 11 may be a substrate (wafer) formed of a semiconductor other than silicon (GaAs, InP, GaN, SiC, or the like), sapphire, glass, ceramic, resin, metal, or the like. In addition, there are no limitations on the kind, number, shape, structure, size, arrangement, and the like of the devices 15. The devices 15 may not be formed on the target object 11. Further, the target object 11 may be a package substrate such as a chip size package (CSP) substrate or a quad flat non-leaded package (QFN) substrate. For example, the package substrate is formed by mounting a plurality of device chips on a predetermined substrate, and covering and sealing the mounted device chips with a resin layer (mold resin). A plurality of packaged devices respectively including the plurality of packaged device chips are manufactured by dividing the package substrate along the predetermined planned dividing lines.

When the target object 11 is subjected to processing, the target object 11 is supported by an annular frame 19 for the convenience of handling (transporting, holding, and the like) of the target object 11. The frame 19 is formed of metal such as stainless steel (SUS). A central portion of the frame 19 is provided with a circular opening portion 19a that penetrates the frame 19 in a thickness direction. Incidentally, the diameter of the opening portion 19a is larger than the diameter of the target object 11, so that the target object 11 can be disposed in the opening portion 19a.

A circular sheet 21 is fixed to the target object 11 and the frame 19. The sheet 21 is a sheet (expandable sheet) that can be expanded by application of an external force. Used as the sheet 21 is, for example, a tape including a circular base material and an adhesive (glue agent) provided on the base material. Resin such as polyolefin or polyvinyl chloride that has high extensibility can be used as the base material. In addition, an epoxy-based, acrylic-based, or rubber-based adhesive or the like can be used as the adhesive.

Incidentally, the adhesive may be an ultraviolet curing resin that is cured by being irradiated with ultraviolet rays.

The sheet 21 is fixed to the target object 11 and the frame 19 so as to cover the opening portion 19a in a state in which the target object 11 is disposed inside the opening portion 19a. Specifically, a central portion of the sheet 21 is affixed to the undersurface 11b side of the target object 11, and an outer circumferential portion of the sheet 21 is affixed to a lower surface side of the frame 19. The target object 11 is thereby supported by the frame 19 via the sheet 21.

However, the sheet 21 may be a sheet (thermocompression bonding sheet) that can be thermocompression-bonded to the target object 11 and the frame 19. The thermocompression bonding sheet is formed of a thermoplastic resin having a lower melting point than the target object 11, and does not include an adhesive (glue agent). Used as the thermocompression bonding sheet is, for example, an olefin-based sheet, a styrene-based sheet, a polyester-based sheet, or the like. Examples of the olefin-based sheet include a polyethylene sheet, a polypropylene sheet, and the like. Examples of the styrene-based sheet include a polystyrene sheet and the like. Examples of the polyester-based sheet include a polyethylene terephthalate sheet, a polyethylene naphthalate sheet, and the like.

A roller (heat roller) internally having a heat source, for example, is used when the thermocompression bonding sheet is fixed to the target object 11 and the frame 19. Specifically, the thermocompression bonding sheet is pressed against the target object 11 and the frame 19 while the heat roller heated to a predetermined temperature is in contact with the thermocompression bonding sheet and thereby heating the thermocompression bonding sheet. Consequently, the thermocompression bonding sheet is softened, brought into close contact with the target object 11 and the frame 19, and thermocompression-bonded thereto.

The thermocompression bonding sheet is heated such that the temperature of the thermocompression bonding sheet is equal to or higher than a softening point of the thermocompression bonding sheet and equal to or lower than a melting point of the thermocompression bonding sheet. However, the thermocompression bonding sheet may not have a definite softening point. In this case, the thermocompression bonding sheet is heated such that the temperature of the thermocompression bonding sheet is equal to or higher than a temperature lower by a predetermined temperature (for example, 20° C.) than the melting point of the thermocompression bonding sheet and equal to or lower than the melting point of the thermocompression bonding sheet. For example, in a case where the thermocompression bonding sheet is a polyethylene sheet, a heating temperature can be set to be equal to or higher than 120° C. and equal to or lower than 140° C., and in a case where the thermocompression bonding sheet is a polypropylene sheet, the heating temperature can be set to be equal to or higher than 160° C. and equal to or lower than 180° C. In addition, in a case where the thermocompression bonding sheet is a polystyrene sheet, the heating temperature can be set to be equal to or higher than 220° C. and equal to or lower than 240° C. Further, in a case where the thermocompression bonding sheet is a polyethylene terephthalate sheet, the heating temperature can be set to be equal to or higher than 250° C. and equal to or lower than 270° C., and in a case where the thermocompression bonding sheet is a polyethylene naphthalate sheet, the heating temperature can be set to be equal to or higher than 160° C. and equal to or lower than 180° C.

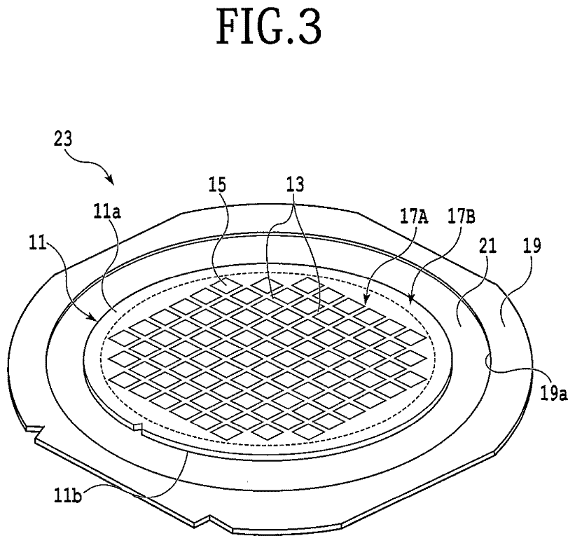

FIG. 3 is a perspective view illustrating a frame unit (target object unit) 23. The frame unit 23 including the target object 11, the frame 19, and the sheet 21 is formed when the target object 11 is supported by the frame 19 via the sheet 21. Then, in a state in which the target object 11 is supported by the frame 19, the transporting, holding, and the like of the target object 11 are performed, and the target object 11 is subjected to predetermined processing. However, the target object 11 may be supported by a member other than the annular frame 19. That is, the sheet 21 do not necessarily need to be fixed to the frame 19.

In the preparing step S1, the frame unit 23 is prepared according to the above-described procedure, for example. Incidentally, a person who performs the sheet processing method according to the present embodiment may form and prepare the frame unit 23 by himself/herself, or may prepare the frame unit 23 by obtaining the frame unit 23 formed by another person.

Next, the processing step S2 of processing the target object 11 is performed. In the present embodiment, a description will be made of a case where the processing step S2 subjects the target object 11 to division processing, and thereby divides the target object 11 into a plurality of chips. The processing step S2 includes, for example, a step of forming division starting points in the target object 11 (division starting point forming step) and a step of applying an external force to the target object 11 (external force applying step).

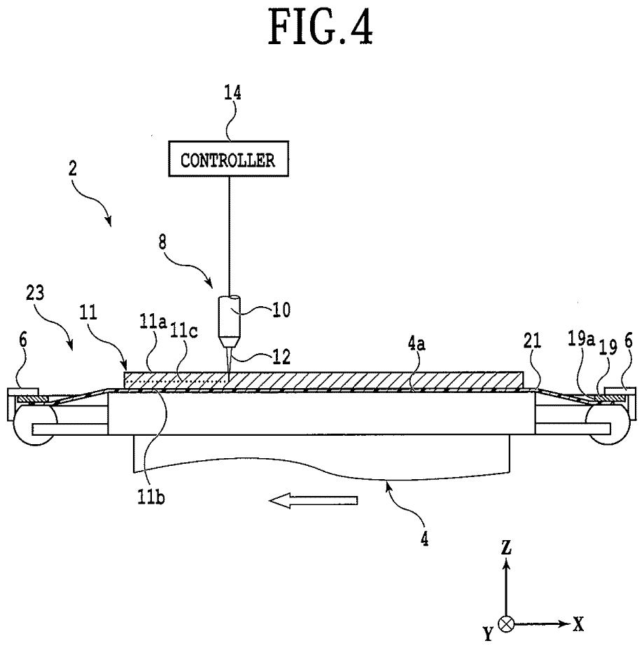

FIG. 4 is a partially sectional front view illustrating a laser processing apparatus 2. The division starting point forming step, for example, forms a modified layer functioning as a division starting point within the target object 11 by subjecting the target object 11 to laser processing by the laser processing apparatus 2. Incidentally, in FIG. 4, an X-axis direction (a processing feed direction or a first horizontal direction) and a Y-axis direction (an indexing feed direction or a second horizontal direction) are directions perpendicular to each other. In addition, a Z-axis direction (an upward-downward direction, a height direction, or a vertical direction) is a direction perpendicular to the X-axis direction and the Y-axis direction.

The laser processing apparatus 2 includes a chuck table (holding table) 4 that holds the target object 11. The upper surface of the chuck table 4 is a circular flat surface substantially parallel with a horizontal plane (XY plane), and constitutes a holding surface 4a that holds the target object 11. The holding surface 4a is connected to a suction source (not illustrated) such as an ejector via a flow passage (not illustrated) formed within the chuck table 4, a valve (not illustrated), and the like.

A ball screw type moving mechanism (not illustrated) that moves the chuck table 4 along the X-axis direction and the Y-axis direction is coupled to the chuck table 4. In addition, a rotational driving source (not illustrated) such as a motor that rotates the chuck table 4 about a rotational axis substantially perpendicular to the holding surface 4a is coupled to the chuck table 4. Further, a plurality of clamps 6 that hold and fix the frame 19 supporting the target object 11 are provided to the periphery of the chuck table 4.

In addition, the laser processing apparatus 2 includes a laser irradiating unit 8 that applies a laser beam. The laser irradiating unit 8 includes a laser oscillator (not illustrated) such as a YAG laser, a YVO₄ laser, or a YLF laser and a laser processing head 10 disposed above the chuck table 4. The laser processing head 10 includes an optical system that guides, to the target object 11, a pulse-oscillating laser beam 12 emitted from the laser oscillator. The optical system includes an optical element such as a condensing lens that condenses the laser beam 12. The laser beam 12 emitted from the laser oscillator is applied from the laser processing head 10 to the target object 11, and is condensed at a predetermined position. Then, the target object 11 is subjected to predetermined laser processing by the laser beam 12.

Further, the laser processing apparatus 2 includes a controller (a control unit, a control section, or a control apparatus) 14 that controls the laser processing apparatus 2. The controller 14 is connected to various constituent elements (the chuck table 4, the clamps 6, the laser irradiating unit 8, and the like) constituting the laser processing apparatus 2, and outputs control signals to the various constituent elements. The controller 14 is, for example, constituted by a computer, which includes a processing unit that performs processing such as computation necessary for the operation of the laser processing apparatus 2 and a storage unit that stores various kinds of information (data, a program, and the like) used for the operation of the laser processing apparatus 2. The processing unit includes a processor such as a central processing unit (CPU). The storage unit includes memories such as a read only memory (ROM) and a random access memory (RAM).

When the target object 11 is to be processed by the laser processing apparatus 2, first, the target object 11 is held by the chuck table 4. For example, the target object 11 is disposed on the chuck table 4 such that the top surface 11a side is oriented upward and such that the undersurface 11b side (sheet 21 side) faces the holding surface 4a. In addition, the frame 19 is fixed by the plurality of clamps 6. When a suction force (negative pressure) of the suction source is made to act on the holding surface 4a in this state, the target object 11 is sucked and held by the chuck table 4 via the sheet 21.

Next, the chuck table 4 is rotated to adjust the angle of the chuck table 4 such that the length direction of a predetermined planned dividing line 13 (see FIG. 3) coincides with the X-axis direction. In addition, a position in the Y-axis direction of the chuck table 4 is adjusted such that a region irradiated with the laser beam 12 is located on an extension of the predetermined planned dividing line 13. Further, the height position of the laser processing head 10 or the arrangement of the optical system is adjusted such that a condensing point of the laser beam 12 is located at a same height position (position in the Z-axis direction) as an internal part (between the top surface 11a and the undersurface 11b) of the target object 11.

Then, the chuck table 4 is moved along the X-axis direction while the laser beam 12 is applied from the laser processing head 10. The chuck table 4 and the laser beam 12 are thereby moved relative to each other along the processing feed direction at a predetermined processing feed speed. As a result, the laser beam 12 is applied along the planned dividing line 13 from the top surface 11a side of the target object 11.

Incidentally, the laser processing apparatus 2 processes the target object 11 under predetermined processing conditions registered in the controller 14 in advance. For example, irradiation conditions of the laser beam 12 are set such that a region of the target object 11 which region is irradiated with the laser beam 12 is modified and altered by multiphoton absorption.

Specifically, the wavelength of the laser beam 12 is set such that at least a part of the laser beam 12 passes through the target object 11. That is, the laser beam 12 is a laser beam transmissible through the target object 11. In addition, the other irradiation conditions of the laser beam 12 are also set so as to modify the target object 11 appropriately. In a case where the target object 11 is a single crystal silicon wafer, for example, the irradiation conditions of the laser beam 12 can be set as follows:
Wavelength: 1064 nm
Average power: 1 W
Repetition frequency: 100 kHz
Processing feed speed: 800 mm/s

When the target object 11 is processed under the above-described processing conditions, the internal part of the target object 11 is modified and altered by multiphoton absorption, and consequently a modified layer (altered layer) 11c is formed in the internal part of the target object 11 along the planned dividing line 13. Thereafter, the laser beam 12 is applied along the other planned dividing lines 13 by repeating a similar procedure. As a result, a plurality of modified layers 11c are formed in a lattice manner in the internal part of the target object 11 along all of the planned dividing lines 13.

Regions in which the modified layers 11c are formed in the target object 11 are more fragile than the other regions of the target object 11. Therefore, when an external force is applied to the target object 11, the target object 11 is divided along the planned dividing lines 13 with the modified layers 11c as a starting point. That is, the modified layers 11c function as a division starting point (trigger for division).

Incidentally, a plurality of modified layers 11c may be formed in the thickness direction of the target object 11. For example, in a case where the target object 11 is a single crystal silicon wafer or the like having a thickness of 200 μm or more, an appropriate division of the target object 11 is facilitated by forming two or more modified layers 11c. In a case of forming the plurality of modified layers 11c, the laser beam 12 is applied along each planned dividing line 13 a plurality of times while the height position of the condensing point of the laser beam 12 is changed.

Next, the target object 11 is divided along the planned dividing lines 13 with the modified layers 11c as a starting point by applying an external force to the target object 11 (external force applying step). For example, in the external force applying step, the external force is applied to the target object 11 by pulling and expanding the sheet 21 fixed to the target object 11. Incidentally, the expansion of the sheet 21 may be performed by using a dedicated expanding apparatus, or may be manually performed by a worker.

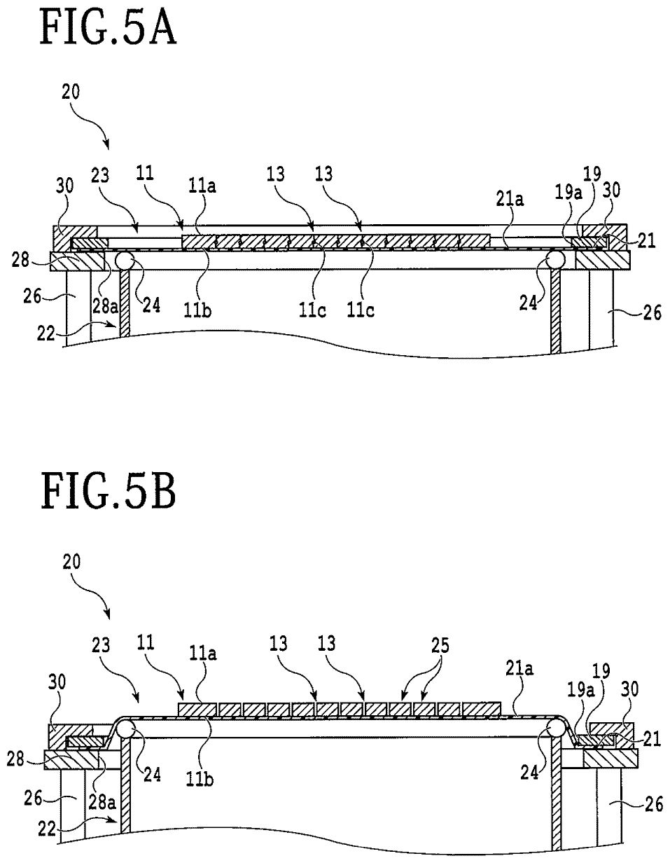

FIG. 5A is a partially sectional front view illustrating an expanding apparatus 20. The expanding apparatus 20 includes a drum 22 formed in a hollow cylindrical shape. On an upper end portion of the drum 22, a plurality of rollers 24 are arranged at substantially equal intervals along the circumferential direction of the drum 22. In addition, a plurality of columnar supporting members 26 are arranged on the outside of the drum 22. Each of lower end portions of the supporting members 26 is coupled with a raising and lowering mechanism (not illustrated) that raises and lowers the supporting member 26 along the vertical direction. Used as the raising and lowering mechanism is, for example, a linear actuator, an air cylinder, or the like.

An annular table 28 is fixed to upper end portions of the plurality of supporting members 26. A central portion of the table 28 is provided with a circular opening portion 28a that penetrates the table 28 in the thickness direction. The diameter of the opening portion 28a is larger than the diameter of the drum 22, so that the upper end portion of the drum 22 can be inserted into the opening portion 28a. In addition, a plurality of clamps 30 that grip and fix the frame 19 supporting the target object 11 are arranged on an outer circumferential portion of the table 28. When the plurality of supporting members 26 are raised or lowered by the raising and lowering mechanisms (not illustrated), the table 28 and the frame 19 are raised or lowered along the vertical direction.

When the target object 11 is to be divided, first, the supporting members 26 are raised or lowered by the raising and lowering mechanisms (not illustrated) to dispose the table 28 at an initial position. When the table 28 is disposed at the initial position, the upper surface of the table 28 and upper ends of the rollers 24 are arranged at substantially a same height position. Then, the frame 19 is disposed onto the table 28, and the frame 19 is fixed by the plurality of clamps 30. At this time, the target object 11 is disposed so as to coincide with the inside of the drum 22. The table 28 and the clamps 30 are thereafter pulled down by lowering the supporting members 26. Thus, the frame 19 is pushed down, and the sheet 21 is stretched in a state of being supported by the rollers 24. As a result, the sheet 21 is radially extended and expanded.

FIG. 5B is a partially sectional front view illustrating the expanding apparatus 20 that expands the sheet 21. When the sheet 21 is extended, an external force directed radially outward of the target object 11 is applied to the target object 11 fixed to the sheet 21. As a result, the target object 11 is ruptured along the planned dividing lines 13 with the modified layers 11c as a division starting point. The target object 11 is thereby divided into a plurality of chips (device chips) 25 respectively including the devices 15 (see FIG. 3). When the division of the target object 11 is completed, the supporting members 26 are raised to dispose the table 28 at the initial position again.

As described above, the plurality of chips 25 are manufactured when the target object 11 is divided along the planned dividing lines 13 in the processing step S2. That is, the sheet processing method according to the present embodiment corresponds to a chip manufacturing method that manufactures the chips 25 by dividing the target object 11.

Here, when the sheet 21 is expanded, a large stretch occurs in an unfixed region 21a, which is a region not fixed to the target object 11, in the sheet 21. When the table 28 is returned to the initial position, slack occurs in the unfixed region 21a. In the frame unit 23 in which the target object 11 is supported by the annular frame 19, an annular region exposed between the target object 11 and the frame 19 without being fixed to the target object 11 or the frame 19 corresponds to the unfixed region 21a. When the sheet 21 is expanded, the unfixed region 21a is supported by the plurality of rollers 24.

When slack occurs in the unfixed region 21a of the sheet 21, an inconvenience occurs in handling the target object 11. For example, when the target object 11 is transported from the expanding apparatus 20 in a state in which slack has occurred in the unfixed region 21a, the target object 11 is in a state of hanging down from the frame 19, and thus the target object 11 tends to sway. There is thus a fear that the chips 25 may collide with each other and thereby the chips 25 may be damaged.

Accordingly, in the present embodiment, after completion of the division of the target object 11, the unfixed region 21a of the sheet 21 is heated and shrunk (contracted). Specifically, the unfixed region 21a is heated and shrunk by bringing a light absorbing member that generates heat by absorbing light into contact with the unfixed region 21a (light absorbing member disposing step S3), and thereafter making the light absorbing member generate heat by irradiating the light absorbing member with light (shrinking step S4). The slack in the sheet 21 is thereby reduced or removed, so that subsequent handling of the target object 11 can be performed appropriately.

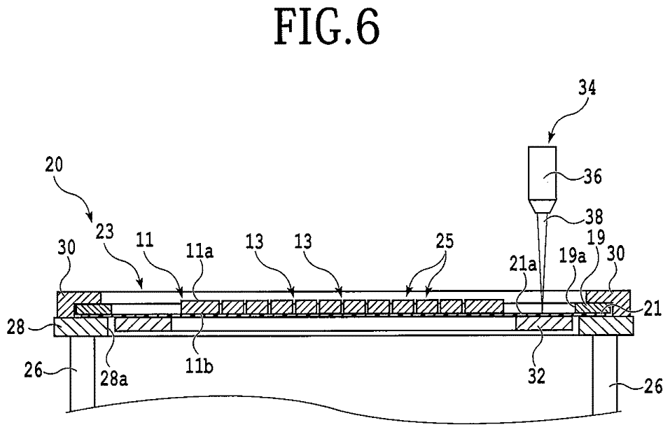

FIG. 6 is a partially sectional front view illustrating the expanding apparatus 20 in the light absorbing member disposing step S3 and the shrinking step S4. In the present embodiment, a description will be made of a case where the light absorbing member disposing step S3 and the shrinking step S4 are performed by using the expanding apparatus 20.

The expanding apparatus 20 includes a light absorbing member 32 that generates heat by absorbing light. The light absorbing member 32 is formed annularly so as to be able to come into contact with the unfixed region 21a of the sheet 21. For example, the outside diameter of the light absorbing member 32 is equal to or less than the inside diameter of the frame 19 (diameter of the opening portion 19a), and the inside diameter of the light absorbing member 32 is equal to or more than the diameter of the target object 11.

The material of the light absorbing member 32 is selected such that when the light absorbing member 32 is irradiated with predetermined light, the light absorbing member 32 generates heat by absorbing the light. That is, the light absorbing member 32 has a property of absorbing the predetermined light. The light absorbing member 32 is, for example, constituted by an annular member formed of metal.

However, in a case where the light absorbing member 32 is held by a predetermined holding member (not illustrated) provided to the expanding apparatus 20, even when the light absorbing member 32 is heated by being irradiated with the light, heat is transmitted from the light absorbing member 32 to the holding member, and the temperature of the light absorbing member 32 tends to be consequently decreased. Therefore, the light absorbing member 32 is preferably formed of a material such as resin that has a low thermal conductivity. For example, the thermal conductivity of the light absorbing member 32 is equal to or lower than 1 W/m·k, preferably equal to or lower than 0.5 W/m·k. This causes the heat generated in the light absorbing member 32 to tend to be retained within the light absorbing member 32, and thus suppresses a decrease in the temperature of the light absorbing member 32.

Examples of the resin that can be used as the material of the light absorbing member 32 include fluorocarbon resins such as polytetrafluoroethylene (PTFE), perfluoroalkoxy alkane (PFA), and ethylene-tetrafluoroethylene copolymer (ETFE). In addition, the resin constituting the light absorbing member 32 may contain a light absorbing material such as carbon so that the light absorbing member 32 absorbs the light more easily. For example, an annular member formed of a fluorocarbon resin containing a carbon fiber or a carbon black is used as the light absorbing member 32.

In addition, the expanding apparatus 20 includes a light irradiating unit 34 that irradiates the light absorbing member 32 with light. The light irradiating unit 34 includes a light irradiation head 36 that applies light 38. The light irradiation head 36 is installed at a position coinciding with the light absorbing member 32. When the light absorbing member 32 is irradiated with the light 38 from the light irradiation head 36, the light absorbing member 32 generates heat by absorbing the light 38. The light irradiating unit 34 is, for example, a laser irradiating unit that applies a laser beam as the light 38. In this case, the light irradiating unit 34 can be formed in a similar manner to the laser irradiating unit 8 (see FIG. 4), and the light irradiation head 36 houses an optical system including optical elements such as a condensing lens. In addition, the wavelength of the light 38 is set such that the light 38 is absorbed by the light absorbing member 32. For example, the wavelength of the light 38 is set to be equal to or more than 700 nm and equal to or less than 1300 nm (typically 940 nm, 1064 nm, or the like).

The light absorbing member 32 and the light irradiation head 36 are arranged such that the sheet 21 is interposed therebetween. For example, in FIG. 6, the light absorbing member 32 is provided under the sheet 21, and the light irradiation head 36 is provided above the sheet 21.

When the unfixed region 21a of the sheet 21 is to be shrunk, the light absorbing member 32 is brought into contact with the unfixed region 21a of the sheet 21 (light absorbing member disposing step S3). In the light absorbing member disposing step S3, first, a space for disposing the light absorbing member 32 is secured on the lower side of the sheet 21. For example, the sheet 21 is separated from the plurality of rollers 24 (see FIG. 5A and FIG. 5B) by raising the table 28 by the raising and lowering mechanisms (not illustrated). A space in which the light absorbing member 32 can be disposed is thereby secured on the lower side of the sheet 21. However, the drum 22 (see FIG. 5A and FIG. 5B) of the expanding apparatus 20 may be installed on a raising and lowering base (not illustrated) that raises and lowers the drum 22. In this case, the plurality of rollers 24 can be separated from the sheet 21 by lowering the drum 22 by the raising and lowering base. Then, the light absorbing member 32 is manually or automatically moved to be brought into contact with the lower surface side of the unfixed region 21a of the sheet 21. The light absorbing member 32 is thereby disposed so as to coincide with the unfixed region 21a in the vertical direction.

However, the light absorbing member 32 may be disposed so as to be in contact with the upper surface side of the unfixed region 21a of the sheet 21. In this case, the light absorbing member 32 is disposed in a gap between the target object 11 and the frame 19, and the light irradiation head 36 is disposed on the lower side of the sheet 21.

Next, the unfixed region 21a of the sheet 21 is heated and shrunk by making the light absorbing member 32 generate heat through irradiation of the light absorbing member 32 with the light 38 (shrinking step S4). In the shrinking step S4, the light irradiating unit 34 is actuated to apply the light 38 from the light irradiation head 36 to the light absorbing member 32. Then, the light 38 passes through the unfixed region 21a of the sheet 21, reaches the light absorbing member 32, and is absorbed by the light absorbing member 32. Consequently, the light 38 applied to the light absorbing member 32 is converted into heat. The light absorbing member 32 thereby generates heat. When the light absorbing member 32 generates heat, the unfixed region 21a of the sheet 21, the unfixed region 21a being in contact with the light absorbing member 32, is heated. Consequently, the unfixed region 21a is shrunk, so that slack occurring in the unfixed region 21a is reduced or removed.

Incidentally, the constituent elements of the expanding apparatus 20 are installed on a rotating base (not illustrated), for example. The rotating base is configured to rotate about a rotational axis set so as to be substantially in parallel with the vertical direction and pass through the center of the table 28. When the rotating base is actuated, the constituent elements (the supporting member 26, the table 28, the clamps 30, and the like) of the expanding apparatus 20 are revolved about the rotational axis of the rotating base. The frame unit 23 and the light absorbing member 32 held by the constituent elements of the expanding apparatus 20 are thereby also rotated.

In the shrinking step S4, the frame unit 23 and the light absorbing member 32 are rotated while the light absorbing member 32 is irradiated with the light 38 from the light irradiation head 36. The light 38 is thereby scanned annularly along the circumferential direction of the light absorbing member 32, and is thus applied over the whole of the light absorbing member 32. As a result, the whole of the unfixed region 21a in contact with the light absorbing member 32 is heated, so that slack in the sheet 21 is reduced or removed over the whole of the unfixed region 21a.

However, the light 38 may be scanned annularly by swinging the light irradiation head 36 instead of rotating the frame unit 23 and the light absorbing member 32. For example, a swinging arm (not illustrated) that swings the light irradiation head 36 along an annular path coinciding with the light absorbing member 32 is connected to the light irradiation head 36. In this case, the light irradiation head 36 is swung by actuating the swinging arm while the light absorbing member 32 is irradiated with the light 38 from the light irradiation head 36. The light 38 can be thereby scanned annularly along the circumferential direction of the light absorbing member 32.

Incidentally, when the sheet 21 is disposed between the light absorbing member 32 and the light irradiation head 36, a surface (contact surface) of the light absorbing member 32 which surface is in contact with the unfixed region 21a is mainly irradiated with the light 38 applied from the light irradiation head 36. Thus, the heat generated by the light absorbing member 32 is easily transmitted to the unfixed region 21a, so that the unfixed region 21a is heated efficiently. However, in a case where the light absorbing member 32 can be sufficiently heated throughout in the thickness direction thereof by being irradiated with the light 38, the light absorbing member 32 and the light irradiation head 36 may both be arranged on the upper side or lower side of the sheet 21. In this case, the light absorbing member 32 is disposed between the sheet 21 and the light irradiation head 36, and a surface (noncontact surface) of the light absorbing member 32 which surface is on an opposite side from the sheet 21 is irradiated with the light 38 from the light irradiation head 36. Then, heat generated on the noncontact surface side of the light absorbing member 32 is transmitted to the contact surface via an internal part of the light absorbing member 32 to heat the unfixed region 21a of the sheet 21.

As described above, even in a case where the sheet 21 does not have a property of absorbing the light 38, the irradiation of the light absorbing member 32 in contact with the unfixed region 21a of the sheet 21 with the light 38 can heat and shrink the unfixed region 21a. It is thereby possible to suppress slack in the sheet 21 irrespective of the material of the sheet 21.

Incidentally, in the above, a description has been made of an example in which the light absorbing member 32 heats the unfixed region 21a of the sheet 21 over an entire area of the unfixed region 21a. However, in the shrinking step S4, only a part of the unfixed region 21a may be heated according to a characteristic of the sheet 21. For example, in a case where slack tends to occur particularly in a predetermined area of the unfixed region 21a of the sheet 21, only the area may be heated and shrunk. Specifically, in the shrinking step S4, switching between irradiation and non-irradiation with the light 38 is performed in predetermined timing while the light 38 is scanned annularly along the light absorbing member 32. As a result, the light 38 is intermittently applied along the light absorbing member 32, and the light absorbing member 32 is partly heated. It is thus possible to heat only the desired area of the unfixed region 21a.

In a case where only a part of the unfixed region 21a is heated, the light absorbing member 32 may be disposed so as to be in contact with only a part of the unfixed region 21a. In this case, the shape of the light absorbing member 32 does not necessarily need to be the annular shape corresponding to the shape of the unfixed region 21a. For example, while a circular or polygonal light absorbing member 32 having a small size so as to be able to be disposed between the target object 11 and the frame 19 is sequentially brought into contact with a plurality of areas of the unfixed region 21a, the light absorbing member 32 may be irradiated with the light 38 in each area. In this case, the light absorbing member disposing step S3 and the shrinking step S4 are alternately performed a plurality of times.

In addition, in the above, a description has been made of a case where slack in the sheet 21 is reduced or removed by performing the light absorbing member disposing step S3 and the shrinking step S4 after the slack occurs in the sheet 21 in the processing step S2. However, it is also possible to suppress the slack in the sheet 21 in the processing step S2 in advance by performing the light absorbing member disposing step S3 and the shrinking step S4 in advance before the processing step S2 is performed. Specifically, before the processing step S2 is performed, the unfixed region 21a of the sheet 21 is heated and shrunk by the above-described procedure (the light absorbing member disposing step S3 and the shrinking step S4). Consequently, the unfixed region 21a of the sheet 21 is in a more tense state than the other region, and the tension of the unfixed region 21a is higher than that of the other region. Therefore, even when the sheet 21 is thereafter expanded in the processing step S2, the unfixed region 21a of the sheet 21 is not easily stretched, and thus slack does not easily occur in the unfixed region 21a. The slack in the sheet 21 is thereby suppressed in advance.

As described above, the sheet processing method (chip manufacturing method) according to the present embodiment makes the light absorbing member 32 in contact with the unfixed region 21a of the sheet 21 generate heat by irradiating the light absorbing member 32 with the light 38, and thereby heats and shrinks the unfixed region 21a. This obviates a need for work of setting the irradiation conditions of the light 38 minutely according to the material of the sheet 21, and thus simplifies the processing of suppressing slack in the sheet 21.

Incidentally, in the foregoing embodiment, a description has been made of a case where the processing of applying an external force to the target object 11 is performed by expanding the sheet 21 in the processing step S2. However, there is no limitation on the processing performed on the target object 11 in the processing step S2. Other examples of the processing step S2 will be described in a second embodiment and a third embodiment to be described later.

In addition, in the foregoing embodiment, a description has been made of a case where the light absorbing member disposing step S3 and the shrinking step S4 are performed by using the expanding apparatus 20 (see FIG. 6). However, the light absorbing member disposing step S3 and the shrinking step S4 may be performed by a sheet processing apparatus prepared separately from the expanding apparatus 20. In this case, the sheet processing apparatus includes the light absorbing member 32 and the light irradiating unit 34 described above. Then, after the expanding apparatus 20 expands the sheet 21, the sheet processing apparatus heats the unfixed region 21a of the sheet 21, and thereby suppresses slack in the sheet 21.

Besides, structures, methods, and the like according to the present embodiment can be modified and implemented as appropriate without departing from the objective scope of the present invention.

### Second Embodiment

In the foregoing first embodiment, a description has been made of a case where slack occurs in the sheet 21 when an external force is applied to the target object 11 by expanding the sheet 21. In the present embodiment, processing of separating an annular reinforcing portion from a target object resulting from TAIKO grinding will be described as another example of the processing performed on the target object.

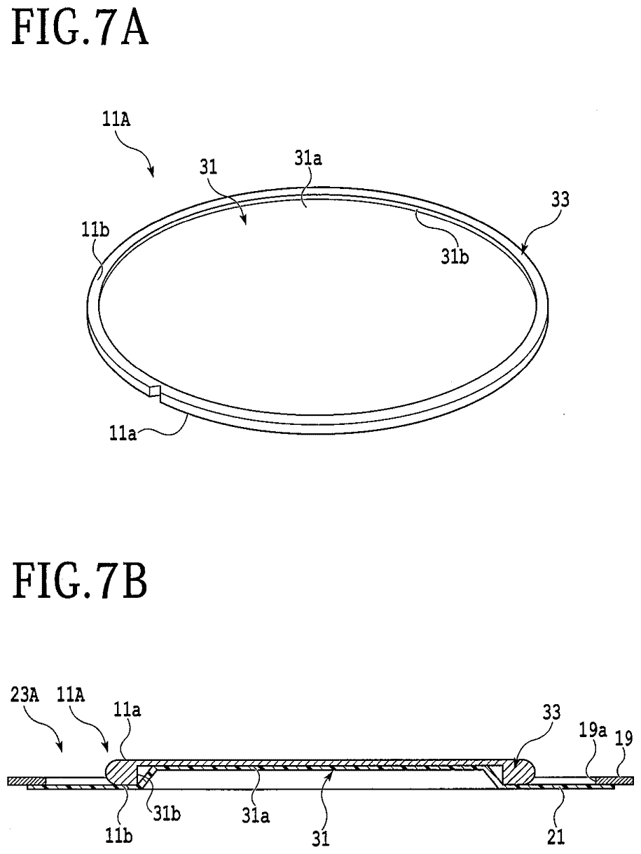

FIG. 7A is a perspective view illustrating a target object 11A as a modification of the target object 11. The configuration, material, and the like of the target object 11A are similar to those of the target object 11 (see FIG. 2) except for items to be described in the following. For example, the target object 11A is a disk-shaped wafer formed of a semiconductor material such as single crystal silicon, and has a top surface 11a and an undersurface 11b that are substantially parallel with each other. In addition, a plurality of devices 15 (see FIG. 1) are formed on the top surface 11a side of the target object 11A, and the target object 11A includes a device region 17A and a peripheral surplus region 17B (see FIG. 1). A plurality of chips 25 (see FIG. 5B) respectively having the devices 15 are manufactured by dividing the target object 11A along planned dividing lines 13 (see FIG. 1). In addition, thinned chips 25 are obtained by grinding and thinning the target object 11A before being divided.

A grinding apparatus, for example, is used to thin the target object 11A. The grinding apparatus includes a chuck table (holding table) that holds the target object 11A, and a grinding unit that performs grinding processing on the target object 11A. The grinding unit is fitted with an annular grinding wheel including a plurality of grinding stones. The target object 11A is held by the chuck table, and the grinding stones are brought into contact with the undersurface 11b side of the target object 11A while the chuck table and the grinding wheel are rotated. The undersurface 11b side of the target object 11A is thereby ground, and thus the target object 11A is thinned.

However, when the whole of the undersurface 11b side of the target object 11A is ground, the whole of the target object 11A is thinned, and thus the rigidity of the target object 11A is decreased. Consequently, the target object 11A tends to be deformed or damaged, and it is difficult to handle the target object 11A after being thinned. Accordingly, thinning processing may be performed on only a part of a region on the undersurface 11b side of the target object 11A. Specifically, TAIKO grinding that grinds only a central portion of the target object 11A is performed on the target object 11A. In this case, a circular recessed portion (groove) 31 is formed in the undersurface 11b of the target object 11A. The recessed portion 31 is provided in a position corresponding to the device region 17A (see FIG. 1). For example, the diameter of the recessed portion 31 is substantially the same as the diameter of the device region 17A, and the recessed portion 31 is formed in a position coinciding with the device region 17A.

The recessed portion 31 includes a circular bottom surface 31a substantially parallel with the top surface 11a and the undersurface 11b of the target object 11A and an annular side surface (inner wall) 31b substantially parallel with the thickness direction of the target object 11A and connected to the undersurface 11b and the bottom surface 31a. In addition, an annular reinforcing portion (protruding portion) 33 corresponding to a region not subjected to the thinning processing (grinding processing) remains in an outer circumferential portion of the target object 11A. The reinforcing portion 33 includes the peripheral surplus region 17B (see FIG. 1), and surrounds the device region 17A (see FIG. 1) and the recessed portion 31.

When only the central portion of the target object 11A is thinned, the outer circumferential portion (reinforcing portion 33) of the target object 11A is maintained in a thick state. A decrease in the rigidity of the target object 11A is thereby suppressed, so that a deformation, damage, or the like in the target object 11A does not easily occur. That is, the reinforcing portion 33 functions as an annular reinforcing member that reinforces the target object 11A.

FIG. 7B is a sectional view illustrating a frame unit 23A as a modification of the frame unit 23. When the target object 11A is to be subjected to predetermined processing, the target object 11A is supported by the frame 19 via the sheet 21. The frame unit 23A including the target object 11A, the frame 19, and the sheet 21 is thereby formed.

When the frame unit 23A is formed, the sheet 21 is fixed to the undersurface 11b side of the target object 11A and the frame 19. At this time, the sheet 21 is fixed along a contour on the undersurface 11b side of the target object 11A while stretched by being pressed against the bottom surface 31a of the recessed portion 31. The sheet 21 is thereby affixed along the recessed portion 31 and the undersurface (lower surface) of the reinforcing portion 33.

The preparing step S1 prepares the target object 11A that has the recessed portion 31 provided to the central portion thereof, has the reinforcing portion 33 provided to the outer circumferential portion thereof, and has the sheet 21 fixed to the recessed portion 31 and the reinforcing portion 33, as described above.

Incidentally, while FIG. 7B illustrates a case where there is a slight gap (space) between the sheet 21 and the bottom surface 31a and the side surface 31b at an outer circumferential portion of the recessed portion 31, the sheet 21 may be fixed so as to be in close contact with the bottom surface 31a and the side surface 31b.

The target object 11A resulting from the TAIKO grinding is processed in a state of being supported by the frame 19 as described above. Then, after the target object 11A is subjected to various kinds of processing, the reinforcing portion 33 is finally separated and removed from the target object 11A. In the present embodiment, a description will be made of a case where the reinforcing portion 33 is separated from the target object 11A in the processing step S2. The processing step S2 includes, for example, a step of forming a separation starting point in the target object 11 (separation starting point forming step) and a step of applying an external force to the target object 11 (external force applying step).

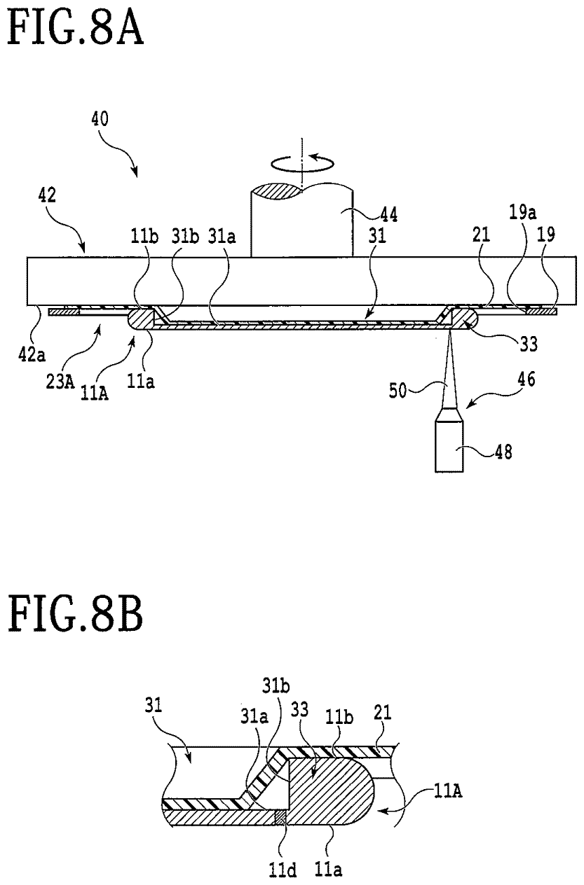

FIG. 8A is a partially sectional front view illustrating a laser processing apparatus 40. The separation starting point forming step, for example, forms a modified region for functioning as a separation starting point in the target object 11A by performing laser processing on the target object 11A in the laser processing apparatus 40.

The laser processing apparatus 40 includes a chuck table (holding table) 42 that holds the frame unit 23A. The lower surface of the chuck table 42 is a circular flat surface substantially parallel with a horizontal plane, and constitutes a holding surface 42a that holds the frame unit 23A. The holding surface 42a is connected to a suction source (not illustrated) such as an ejector via a flow passage (not illustrated) formed within the chuck table 42, a valve (not illustrated), and the like.

The upper surface side of the chuck table 42 is connected with a circular cylindrical supporting shaft 44 that supports the chuck table 42. A distal end portion (lower end portion) of the supporting shaft 44 is fixed to a central portion of the upper surface side of the chuck table 42. A proximal end portion (upper end portion) of the supporting shaft 44 is coupled with a rotational driving source (not illustrated) such as a motor that rotates the supporting shaft 44. When the rotational driving source is actuated, the chuck table 42 and the supporting shaft 44 are rotated about a rotational axis substantially parallel with the vertical direction. In addition, the supporting shaft 44 is coupled with a moving mechanism (not illustrated) that moves the chuck table 42 and the supporting shaft 44 along a horizontal direction and the vertical direction.

In addition, the laser processing apparatus 40 includes a laser irradiating unit 46 that applies a laser beam. The laser irradiating unit 46 has a configuration and functions similar to those of the laser irradiating unit 8 (see FIG. 4) in the laser processing apparatus 2. Specifically, the laser irradiating unit 46 includes a laser oscillator (not illustrated) and a laser processing head 48 disposed below the chuck table 42. The laser processing head 48 includes an optical system that guides, to the target object 11A, a pulse-oscillating laser beam 50 emitted from the laser oscillator. The optical system includes an optical element such as a condensing lens that condenses the laser beam 50. The laser beam 50 emitted from the laser oscillator is applied from the laser processing head 48 to the target object 11A, and is condensed at a predetermined position. Then, the target object 11A is subjected to predetermined laser processing by the laser beam 50.

Further, the laser processing apparatus 40 includes a controller (not illustrated) that controls the laser processing apparatus 40. The controller has a configuration and functions similar to those of the controller 14 (see FIG. 4) in the laser processing apparatus 2.

The separation starting point forming step forms a separation starting point at a time of separating the reinforcing portion 33 from the target object 11A. Specifically, first, the frame unit 23A is held by the chuck table 42. For example, the frame unit 23A is in contact with the holding surface 42a such that the top surface 11a side of the target object 11A is oriented downward and such that the undersurface 11b side (sheet 21 side) of the target object 11A faces the holding surface 42a. When a suction force (negative pressure) of the suction source is made to act on the holding surface 42a in this state, the target object 11A and the frame 19 are sucked and held by the chuck table 42 via the sheet 21. Incidentally, the chuck table 42 may have a plurality of clamps (not illustrated) that grip the frame 19.

Next, positional relation in the horizontal direction between the chuck table 42 and the laser processing head 48 is adjusted such that a region in which to form a separation starting point (processing target region) in the target object 11A coincides with the laser processing head 48 in the vertical direction. In addition, the condensing position of the laser beam 50 is adjusted such that the laser beam 50 is condensed in the processing target region of the target object 11A. In the present embodiment, an outer circumferential portion of the recessed portion 31 formed in the target object 11A (vicinity of a boundary between the recessed portion 31 and the reinforcing portion 33) is set as the processing target region. Then, the chuck table 42 is rotated while the laser beam 50 is applied from the laser processing head 48. The laser beam 50 is thereby scanned annularly along the processing target region of the target object 11A (outer circumferential portion of the recessed portion 31). Incidentally, irradiation conditions of the laser beam 50 can be set similarly to those at a time of forming the modified layer 11c in the target object 11 (see FIG. 4).

FIG. 8B is a sectional view illustrating a part of the target object 11A in which a modified region (altered region) 11d is formed. When the target object 11A is irradiated with the laser beam 50 as described above, an internal part of the target object 11A is modified and altered by multiphoton absorption, and consequently an annular modified region 11d is formed in the outer circumferential portion of the recessed portion 31 of the target object 11A. Incidentally, the modified region 11d may be formed so as to extend from the top surface 11a of the target object 11 to the bottom surface 31a of the recessed portion 31, or may be formed in a partial region between the top surface 11a of the target object 11 and the bottom surface 31a of the recessed portion 31.

An area in which the modified region 11d is formed in the target object 11A is more fragile than the other area of the target object 11A. Therefore, when an external force is applied to the target object 11A, the target object 11A is ruptured with the modified region 11d as a starting point, and the reinforcing portion 33 is separated from the target object 11A. That is, the modified region 11d functions as a separation starting point (trigger for separation).

It is to be noted that, while, in the above, a description has been made of a case where the modified region 11d is formed in the target object 11A, the separation starting point is not limited to the modified region 11d. For example, a groove (laser-processed groove) that functions as the separation starting point may be formed in the outer circumferential portion of the recessed portion 31 by performing ablation processing on the target object 11A. In this case, the wavelength of the laser beam 50 is set such that at least a part of the laser beam 50 is absorbed by the target object 11A. That is, a laser beam 50 absorbable by the target object 11A is used.

Next, the reinforcing portion 33 is separated from the target object 11A with the modified region 11d as a starting point by applying an external force to the target object 11A (external force applying step). For example, the external force applying step applies the external force by pressing a predetermined member (tool) against the reinforcing portion 33. Incidentally, the separation of the reinforcing portion 33 from the target object 11A may be performed by using a dedicated separating apparatus, or may be manually performed by the worker.

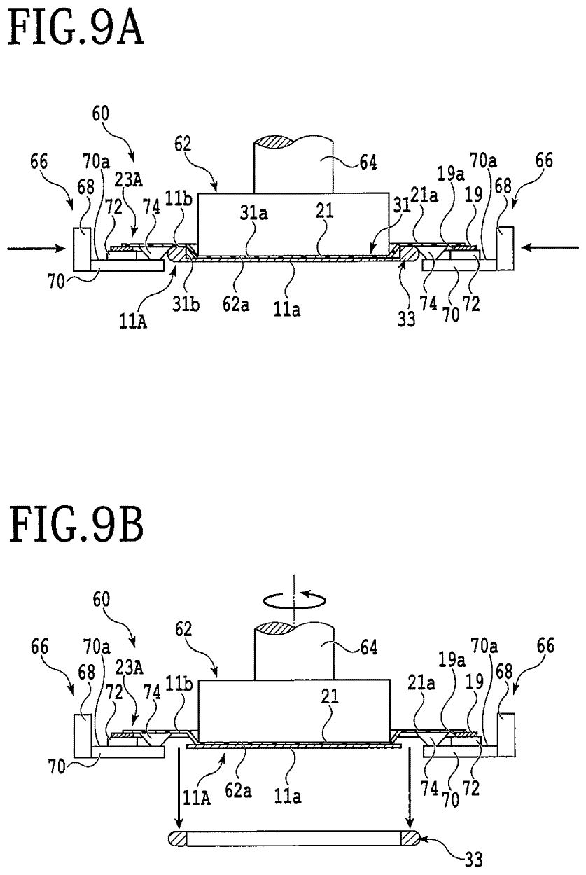

FIG. 9A is a partially sectional front view illustrating a separating apparatus 60 at a time of applying an external force to the target object 11A. The separating apparatus 60 includes a chuck table (holding table) 62 that holds the target object 11A. The lower surface of the chuck table 62 is a circular flat surface substantially parallel with the horizontal plane, and constitutes a holding surface 62a that holds the target object 11A. The holding surface 62a is connected to a suction source (not illustrated) such as an ejector via a flow passage (not illustrated) formed within the chuck table 62, a valve (not illustrated), and the like. Incidentally, the diameter of the holding surface 62a side of the chuck table 62 is set to be less than the diameter of the recessed portion 31 formed in the target object 11A. The holding surface 62a side of the chuck table 62 can therefore be inserted into the recessed portion 31 of the target object 11A.

The upper surface side of the chuck table 62 is connected with a circular cylindrical supporting shaft 64 that supports the chuck table 62. A distal end portion (lower end portion) of the supporting shaft 64 is fixed to a central portion of the upper surface side of the chuck table 62. A proximal end portion (upper end portion) of the supporting shaft 64 is coupled with a rotational driving source (not illustrated) such as a motor that rotates the supporting shaft 64. When the rotational driving source is actuated, the chuck table 62 and the supporting shaft 64 are rotated about a rotational axis substantially parallel with the vertical direction. In addition, the supporting shaft 64 is coupled with a moving mechanism (not illustrated) that moves the chuck table 62 and the supporting shaft 64 along the horizontal direction and the vertical direction.

Paired external force applying units 66 that apply an external force to the target object 11A are provided on both sides (a right side and a left side in FIG. 9A) of the chuck table 62. Each of the paired external force applying units 66 includes a columnar movable member 68 and a flat plate-shaped supporting member 70 that projects in the horizontal direction from a lower end portion of the movable member 68.

The movable member 68 is coupled with a moving mechanism (not illustrated) that moves the movable member 68 along the horizontal direction and the vertical direction. The moving mechanism includes, for example, a linear actuator that moves the movable member 68 along the horizontal direction and an air cylinder that moves (raises or lowers) the movable member 68 along the vertical direction. However, there is no limitation on the kind, configuration, functions, and the like of the moving mechanism as long as the moving mechanism can move the movable member 68.

The supporting member 70 is fixed to a lower end portion of the movable member 68, and projects from the movable member 68 to the chuck table 62 side. In addition, the upper surface of the supporting member 70 is a flat surface substantially parallel with the horizontal plane, and constitutes a supporting surface 70a that supports constituent elements of the external force applying unit 66.

A frame support base 72 that supports the frame 19 is provided on the supporting surface 70a of the supporting member 70. For example, the frame support base 72 is a disk-shaped member formed of metal, resin, or the like. The frame support base 72 supports the frame 19 from below.

In addition, a tool (pressing member) 74 that applies an external force to the reinforcing portion 33 of the target object 11A is provided on the supporting surface 70a of the supporting member 70. For example, the tool 74 is formed of metal, resin, or the like, and is formed in a shape of an inverted circular truncated cone that increases in diameter toward an upper surface side from a lower surface side. Therefore, an angle formed between the upper surface and the side surface of the tool 74 is an acute angle, and a sharp angular portion is formed at an edge portion on an upper end side of the tool 74. However, the shape of the tool 74 is not limited to the shape of an inverted circular truncated cone, but may be the shape of an inverted polygonal truncated pyramid, for example.

The tool 74 is provided at a position closer to the chuck table 62 than the frame support base 72. That is, the tool 74 is disposed between the chuck table 62 and the frame support base 72 as viewed in plan.

Incidentally, while FIG. 9A illustrates one frame support base 72 and one tool 74 provided on the supporting surface 70a of the supporting member 70, two or more frame support bases 72 and two or more tools 74 may be provided on the supporting surface 70a of the supporting member 70.

In the external force applying step, first, the target object 11A is held by the chuck table 62. Specifically, the target object 11A is disposed on the lower side of the chuck table 62 such that the top surface 11a side is oriented downward and such that the undersurface 11b side (sheet 21 side) faces the holding surface 62a. At this time, the target object 11A is positioned such that the holding surface 62a side of the chuck table 62 is inserted in the recessed portion 31. When a suction force (negative pressure) of the suction source is made to act on the holding surface 62a in this state, the bottom surface 31a of the recessed portion 31 of the target object 11A is sucked and held by the chuck table 62 via the sheet 21. In addition, the paired external force applying units 66 are positioned such that the frame 19 is supported by the frame support bases 72.

Next, the paired external force applying units 66 approach each other so as to sandwich the frame unit 23A therebetween. The target object 11A is thereby sandwiched by the pair of tools 74. At this time, the side surfaces of the tools 74 come into contact with the reinforcing portion 33 of the target object 11A, and upper end portions (angular portions) of the tools 74 enter between the sheet 21 and the reinforcing portion 33. An external force directed obliquely downward is thereby applied to the reinforcing portion 33. In addition, the reinforcing portion 33 is partly peeled off from the sheet 21, and thus a trigger for the peeling of the reinforcing portion 33 from the sheet 21 is given.

Then, the chuck table 62 is rotated in a state in which the tools 74 are in contact with the reinforcing portion 33. Thus, the whole of the annular reinforcing portion 33 comes into contact with the tools 74, and an external force is applied to the whole of the reinforcing portion 33. In addition, a trigger for peeling is formed in the whole of an annular contact region in which the sheet 21 and the reinforcing portion 33 are in contact with each other.

FIG. 9B is a partially sectional front view illustrating the separating apparatus 60 at a time of separating the reinforcing portion 33 from the target object 11A. When the external force is applied to the reinforcing portion 33 as described above, the target object 11A is ruptured with the annular modified region 11d (see FIG. 8B) as a starting point. The reinforcing portion 33 is thereby separated from the target object 11A. In addition, the reinforcing portion 33 is peeled off from and falls off the sheet 21. The reinforcing portion 33 is thus removed from the target object 11A.

Incidentally, in a case where the tools 74 are formed in the shape of an inverted circular truncated cone, the tools 74 may be configured to be rotatable with central axes thereof as a rotational axis. In this case, when the chuck table 62 is rotated, the tools 74 rotate with the rotation of the target object 11A. A friction acting between the reinforcing portion 33 and the tools 74 is thereby reduced, so that the target object 11A can be rotated smoothly.

When the reinforcing portion 33 is separated from the target object 11A in the processing step S2 as described above, a part of the target object 11A other than the reinforcing portion 33 remains as a plate-shaped substrate. That is, the sheet processing method according to the present embodiment corresponds to a substrate manufacturing method that manufactures a substrate by processing the target object 11.

Here, as described above, in a case where the target object 11A is provided with the recessed portion 31, the sheet 21 is fixed in a state of being stretched by being pressed against the bottom surface 31a of the recessed portion 31 (see FIG. 7B). Then, when the reinforcing portion 33 is separated from the target object 11A in the processing step S2, the tension of the sheet 21 fixed to the recessed portion 31 of the target object 11A is released, and slack occurs in the unfixed region 21a of the sheet 21.

Accordingly, in the present embodiment, the unfixed region 21a of the sheet 21 is heated and shrunk by performing the light absorbing member disposing step S3 and the shrinking step S4 after the reinforcing portion 33 is separated from the target object 11A. The slack in the sheet 21 is thereby reduced or removed. Incidentally, contents of the light absorbing member disposing step S3 and the shrinking step S4 are similar to those of the first embodiment except for items to be described in the following (see FIG. 6).

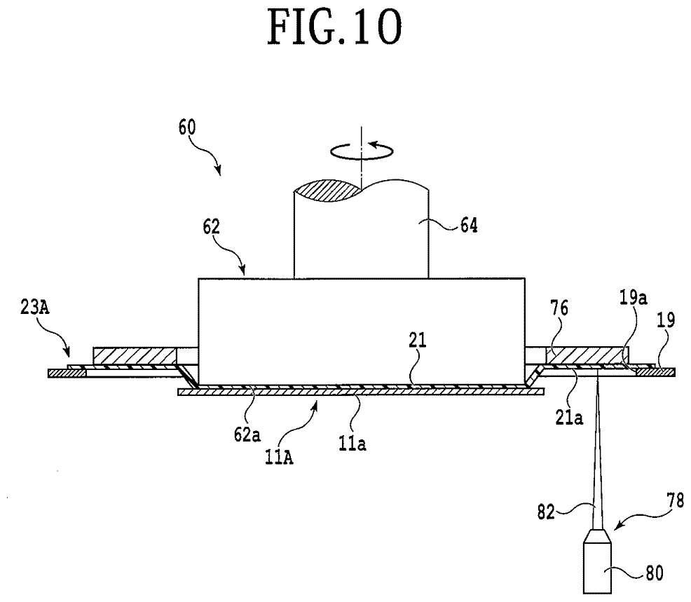

FIG. 10 is a partially sectional front view illustrating the separating apparatus 60 in the light absorbing member disposing step S3 and the shrinking step S4. In the present embodiment, a description will be made of a case where the light absorbing member disposing step S3 and the shrinking step S4 are performed by using the separating apparatus 60.

The separating apparatus 60 includes a light absorbing member 76 that generates heat by absorbing light. The light absorbing member 76 is formed annularly so as to be able to come into contact with the unfixed region 21a of the sheet 21. For example, the outside diameter of the light absorbing member 76 is equal to or less than the inside diameter of the frame 19 (diameter of the opening portion 19a), and the inside diameter of the light absorbing member 76 is equal to or more than the diameter of the recessed portion 31 (see FIG. 7A and FIG. 7B) of the target object 11A. Incidentally, an example of the material of the light absorbing member 76 is similar to that of the light absorbing member 32 (see FIG. 6) described above.

The light absorbing member 76 is, for example, fitted to the chuck table 62 in a state in which the light absorbing member 76 is movable (raisable and lowerable) along the vertical direction. In this case, the light absorbing member 76 is disposed so as to surround the chuck table 62. However, the light absorbing member 76 may be supported by a constituent element other than the chuck table 62.

In addition, the separating apparatus 60 includes a light irradiating unit 78 that irradiates the light absorbing member 76 with light. The light irradiating unit 78 includes a light irradiation head 80 that applies light 82. The light irradiation head 80 is installed at a position coinciding with the light absorbing member 76. When the light absorbing member 76 is irradiated with the light 82 from the light irradiation head 80, the light absorbing member 76 generates heat by absorbing the light 82.

The light irradiating unit 78 is configured in a similar manner to the light irradiating unit 34 (see FIG. 6) of the expanding apparatus 20. For example, the light irradiating unit 78 is a laser irradiating unit that applies a laser beam as the light 82. The wavelength of the light 82 is set as appropriate such that the light 82 is absorbed by the light absorbing member 76.

The light absorbing member 76 and the light irradiation head 80 are arranged such that the sheet 21 is interposed therebetween. For example, in FIG. 10, the light absorbing member 76 is provided on the sheet 21, and the light irradiation head 80 is provided below the sheet 21.

When the unfixed region 21a of the sheet 21 is to be shrunk, first, the light absorbing member 76 is brought into contact with the unfixed region 21a of the sheet 21 (light absorbing member disposing step S3). For example, in the light absorbing member disposing step S3, the light absorbing member 76 is brought into contact with the upper surface side of the unfixed region 21a of the sheet 21 by manually or automatically moving the light absorbing member 76. The light absorbing member 76 is thereby disposed so as to coincide with the unfixed region 21a in the vertical direction. In addition, the paired external force applying units 66 (see FIG. 9A and FIG. 9B) are moved so as to be moved away from the chuck table 62. The paired external force applying units 66 are thereby retreated from a region between the light absorbing member 76 and the light irradiation head 80. Incidentally, after the paired external force applying units 66 are retreated, the frame 19 may be held from the upper side thereof by a holding member (not illustrated) provided to the separating apparatus 60.

The unfixed region 21a of the sheet 21 is thus disposed between the light absorbing member 76 and the light irradiation head 80. Incidentally, the light absorbing member 76 may be disposed so as to be in contact with the lower surface side of the unfixed region 21a of the sheet 21. In this case, the light irradiation head 80 is disposed at a position on the upper side of the sheet 21, the position coinciding with the light absorbing member 76.

Next, the unfixed region 21a of the sheet 21 is heated and shrunk by making the light absorbing member 76 generate heat through irradiation of the light absorbing member 76 with the light 82 (shrinking step S4). In the shrinking step S4, the light irradiating unit 78 is actuated to apply the light 82 from the light irradiation head 80 to the light absorbing member 76. Then, the light 82 passes through the unfixed region 21a of the sheet 21, reaches the light absorbing member 76, and is absorbed by the light absorbing member 76. Consequently, the light 82 applied to the light absorbing member 76 is converted into heat. The light absorbing member 76 thereby generates heat. When the light absorbing member 76 generates heat, the unfixed region 21a of the sheet 21, the unfixed region 21a being into contact with the light absorbing member 76, is heated. Consequently, the unfixed region 21a is shrunk, so that slack occurring in the unfixed region 21a is reduced or removed.

Then, the chuck table 62 is rotated while the light absorbing member 76 is irradiated with the light 82 from the light irradiation head 80. Thus, the light absorbing member 76 is rotated together with the frame unit 23A, and the light 82 is scanned annularly along the circumferential direction of the light absorbing member 76. As a result, the light 82 is applied over the whole of the light absorbing member 76, and the whole of the unfixed region 21a in contact with the light absorbing member 76 is heated.

However, the light 82 may be scanned annularly by swinging the light irradiation head 80 instead of rotating the frame unit 23A and the light absorbing member 76. For example, a swinging arm (not illustrated) that swings the light irradiation head 80 along an annular path coinciding with the light absorbing member 76 is connected to the light irradiation head 80. In this case, the light irradiation head 80 is swung by actuating the swinging arm while the light absorbing member 76 is irradiated with the light 82 from the light irradiation head 80. The light 82 can be thereby scanned annularly along the circumferential direction of the light absorbing member 76.

Incidentally, in a case where the light absorbing member 76 can be sufficiently heated throughout in the thickness direction thereof by being irradiated with the light 82, the light absorbing member 76 and the light irradiation head 80 may both be arranged on the upper side or lower side of the sheet 21. In this case, the light absorbing member 76 is disposed between the sheet 21 and the light irradiation head 80, and a surface of the light absorbing member 76 which surface is on an opposite side from the sheet 21 is irradiated with the light 82 from the light irradiation head 80.

As described above, even in a case where the sheet 21 does not have a property of absorbing the light 82, the irradiation of the light absorbing member 76 in contact with the unfixed region 21a of the sheet 21 with the light 82 can heat and shrink the unfixed region 21a. It is thereby possible to suppress slack in the sheet 21 irrespective of the material of the sheet 21.

Incidentally, in the above, a description has been made of an example in which the light absorbing member 32 heats the unfixed region 21a of the sheet 21 over an entire area of the unfixed region 21a. However, in the shrinking step S4, only a part of the unfixed region 21a may be heated according to a characteristic of the sheet 21. For example, in a case where slack tends to occur particularly in a predetermined area of the unfixed region 21a of the sheet 21, only the area may be heated and shrunk. A concrete example of a method for heating only the part of the unfixed region 21a is similar to that in the first embodiment.

In addition, in the above, a description has been made of a case where slack in the sheet 21 is reduced or removed by performing the light absorbing member disposing step S3 and the shrinking step S4 after the slack occurs in the sheet 21 in the processing step S2. However, it is also possible to suppress the slack in the sheet 21 in the processing step S2 in advance by performing the light absorbing member disposing step S3 and the shrinking step S4 in advance before the processing step S2 is performed. Specifically, before the processing step S2 is performed, the unfixed region 21a of the sheet 21 is heated and shrunk by the above-described procedure (the light absorbing member disposing step S3 and the shrinking step S4). Consequently, the unfixed region 21a of the sheet 21 is in a more tense state than the other region, and the tension of the unfixed region 21a is higher than that of the other region. Therefore, even when the reinforcing portion 33 is thereafter separated from the target object 11A in the processing step S2, slack does not easily occur in the unfixed region 21a.

As described above, the sheet processing method (substrate manufacturing method) according to the present embodiment makes the light absorbing member 76 in contact with the unfixed region 21a of the sheet 21 generate heat by irradiating the light absorbing member 76 with the light 82, and thereby heats and shrinks the unfixed region 21a. This obviates a need for work of setting the irradiation conditions of the light 82 minutely according to the material of the sheet 21, and thus simplifies the processing of suppressing slack in the sheet 21.

Incidentally, in the foregoing embodiment, a description has been made of a case where the light absorbing member disposing step S3 and the shrinking step S4 are performed by using the separating apparatus 60 (see FIG. 10). However, the light absorbing member disposing step S3 and the shrinking step S4 may be performed by a sheet processing apparatus prepared separately from the separating apparatus 60. In this case, the sheet processing apparatus includes the light absorbing member 76 and the light irradiating unit 78 described above. Then, after the separating apparatus 60 separates the reinforcing portion 33 from the target object 11A, the sheet processing apparatus heats the unfixed region 21a of the sheet 21, and thereby suppresses slack in the sheet 21.

Besides, structures, methods, and the like according to the present embodiment can be modified and implemented as appropriate without departing from the objective scope of the present invention. In addition, the present embodiment can be combined with the first embodiment as appropriate, and descriptions in the first embodiment can be incorporated as appropriate for items not described in the present embodiment.

### Third Embodiment

In the foregoing first embodiment, a description has been made of a chip manufacturing method that divides the target object 11 into a plurality of chips 25 by expanding the sheet 21 (see FIG. 5B). However, when the chips 25 are manufactured, the sheet 21 may be expanded also at other than a time of division of the target object 11. In the following, a description will be made of a mode in which the sheet 21 is expanded after the target object 11 is divided into a plurality of chips 25.

In a sheet processing method (chip manufacturing method) according to the present embodiment, first, the target object 11 is divided into a plurality of chips 25 in the processing step S2 (dividing step). In the present embodiment, a description will be made of a method for dividing the target object 11 which method is different from that of the first embodiment.

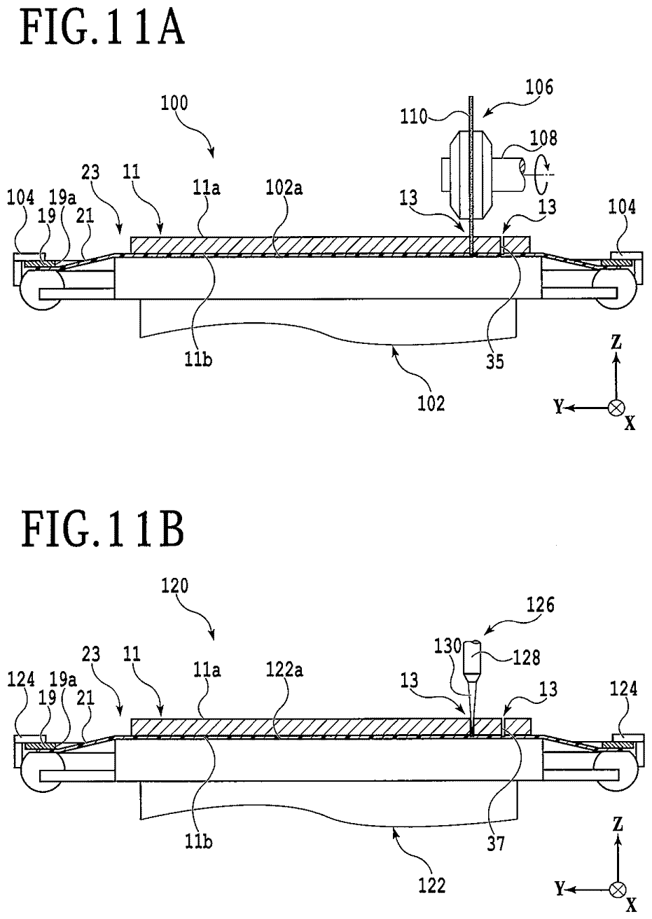

FIG. 11A is a sectional view illustrating the target object 11 to be divided by cutting processing. The dividing step, for example, may divide the target object 11 by cutting the target object 11 along the planned dividing lines 13 by an annular cutting blade. A cutting apparatus 100, for example, is used for the cutting processing of the target object 11.

The cutting apparatus 100 includes a chuck table (holding table) 102 that holds the target object 11. The upper surface of the chuck table 102 is a circular flat surface substantially parallel with a horizontal plane (XY plane), and constitutes a holding surface 102a that holds the target object 11. The holding surface 102a is connected to a suction source (not illustrated) such as an ejector via a flow passage (not illustrated) formed within the chuck table 102, a valve (not illustrated), and the like.

The chuck table 102 is coupled with a ball screw type moving mechanism (not illustrated) that moves the chuck table 102 along the X-axis direction. In addition, the chuck table 102 is coupled with a rotational driving source (not illustrated) such as a motor that rotates the chuck table 102 about a rotational axis substantially perpendicular to the holding surface 102a. Further, a plurality of clamps 104 that grip and fix the frame 19 supporting the target object 11 are provided on the periphery of the chuck table 102.

In addition, the cutting apparatus 100 includes a cutting unit 106 that performs the cutting processing. The cutting unit 106 is installed above the chuck table 102. The cutting unit 106 includes a cylindrical spindle 108 that is disposed along the Y-axis direction. A distal end portion of the spindle 108 is fitted with an annular cutting blade 110. In addition, the cutting unit 106 is coupled with a ball screw type moving mechanism (not illustrated) that moves the cutting unit 106 along the Y-axis direction and the Z-axis direction.

A hub type cutting blade (hub blade), for example, is used as the cutting blade 110. The hub blade includes an annular hub base formed of metal such as an aluminum alloy and an annular cutting edge formed along an outer circumferential edge of the hub base. The cutting edge of the hub blade is constituted by an electroformed grindstone including abrasive grains formed of diamond, cubic boron nitride (cBN), or the like and a binder of a nickel plating layer or the like for fixing the abrasive grains. However, a washer type blade (washer blade) can also be used as the cutting blade 110. The washer blade is constituted by only an annular cutting edge including abrasive grains and a binder formed of metal, ceramic, resin, or the like for fixing the abrasive grains.

When the target object 11 is to be divided by the cutting apparatus 100, first, the target object 11 is held by the chuck table 102. For example, the target object 11 is disposed on the chuck table 102 such that the top surface 11a side is oriented upward and such that the undersurface 11b side (sheet 21 side) faces the holding surface 102a. In addition, the frame 19 is fixed by the plurality of clamps 104. When a suction force (negative pressure) of the suction source is made to act on the holding surface 102a in this state, the target object 11 is sucked and held by the chuck table 102 via the sheet 21.

Next, the chuck table 122 is rotated to adjust the angle of the chuck table 102 such that the length direction of a predetermined planned dividing line 13 coincides with the X-axis direction. In addition, a position in the Y-axis direction of the cutting unit 106 is adjusted such that the cutting blade 110 is located on an extension of the predetermined planned dividing line 13. Further, the height of the cutting unit 106 is adjusted such that a lower end of the cutting blade 110 is disposed below the undersurface 11b of the target object 11 (upper surface of the sheet 21) and above the holding surface 102a (lower surface of the sheet 21).

Then, the chuck table 102 is moved along the X-axis direction while the cutting blade 110 is rotated. Thus, the chuck table 102 and the cutting blade 110 are moved relative to each other along the X-axis direction (processing feed), and the cutting blade 110 cuts the target object 11 along the planned dividing line 13. As a result, a groove (cut groove) 35 extending from the top surface 11a to the undersurface 11b of the target object 11 is formed along the planned dividing line 13. Then, when grooves 35 are formed along all of the planned dividing lines 13, the target object 11 is divided into a plurality of chips 25.

FIG. 11B is a sectional view illustrating the target object 11 to be divided by laser processing. The dividing step may divide the target object 11 by applying a laser beam along the planned dividing lines 13. A laser processing apparatus 120, for example, is used for the laser processing of the target object 11.

The laser processing apparatus 120 includes a chuck table (holding table) 122 that holds the target object 11. The upper surface of the chuck table 122 is a circular flat surface substantially parallel with the horizontal plane (XY plane), and constitutes a holding surface 122a that holds the target object 11. The holding surface 122a is connected to a suction source (not illustrated) such as an ejector via a flow passage (not illustrated) formed within the chuck table 122, a valve (not illustrated), and the like.

The chuck table 122 is coupled with a ball screw type moving mechanism (not illustrated) that moves the chuck table 122 along the X-axis direction and the Y-axis direction. In addition, the chuck table 122 is coupled with a rotational driving source (not illustrated) such as a motor that rotates the chuck table 122 about a rotational axis substantially perpendicular to the holding surface 122a. Further, a plurality of clamps 124 that grip and fix the frame 19 supporting the target object 11 are provided on the periphery of the chuck table 122.

In addition, the laser processing apparatus 120 includes a laser irradiating unit 126 that applies a laser beam. The laser irradiating unit 126 includes a laser oscillator (not illustrated) such as a YAG laser, a YVO₄ laser, or a YLF laser and a laser processing head 128 disposed above the chuck table 122.

The laser processing head 128 includes an optical system that guides, to the target object 11, a pulse-oscillating laser beam 130 emitted from the laser oscillator. The optical system includes an optical element such as a condensing lens that condenses the laser beam 130. The laser beam 130 emitted from the laser oscillator is applied from the laser processing head 128 to the target object 11, and is condensed at a predetermined position. Then, the target object 11 is subjected to predetermined laser processing by the laser beam 130.

When the target object 11 is to be divided by the laser processing apparatus 120, first, the target object 11 is held by the chuck table 122. For example, the target object 11 is disposed on the chuck table 122 such that the top surface 11a side is oriented upward and such that the undersurface 11b side (sheet 21 side) faces the holding surface 122a. In addition, the frame 19 is fixed by the plurality of clamps 124. When a suction force (negative pressure) of the suction source is made to act on the holding surface 122a in this state, the target object 11 is sucked and held by the chuck table 122 via the sheet 21.

Next, the chuck table 122 is rotated to adjust the angle of the chuck table 122 such that the length direction of a predetermined planned dividing line 13 coincides with the X-axis direction. In addition, a position in the Y-axis direction of the chuck table 122 is adjusted such that a region irradiated with the laser beam 130 is located on an extension of the predetermined planned dividing line 13. Further, the height position of the laser processing head 128 or the arrangement of the optical system is adjusted such that a condensing point of the laser beam 130 is located at a same height position as the target object 11.

Then, the chuck table 122 is moved along the X-axis direction while the laser beam 130 is applied from the laser processing head 128. The chuck table 122 and the laser beam 130 are thereby moved relative to each other along the processing feed direction at a predetermined processing feed speed. As a result, the laser beam 130 is applied along the planned dividing line 13 from the top surface 11a side of the target object 11.

Irradiation conditions of the laser beam 130 are set such that the target object 11 is subjected to ablation processing. Specifically, the wavelength of the laser beam 130 is set such that at least a part of the laser beam 130 is absorbed by the target object 11. That is, the laser beam 130 has absorbability by the target object 11. In addition, the other irradiation conditions of the laser beam 130 are also set as appropriate such that the target object 11 is subjected to appropriate ablation processing. In a case where the target object 11 is a single crystal silicon wafer, for example, the irradiation conditions of the laser beam 130 can be set as follows.
Wavelength: 355 nm
Average power: 2 W
Repetition frequency: 200 kHz
Processing feed speed: 400 mm/s

When the target object 11 is processed under the above-described processing conditions, ablation processing is performed along the planned dividing line 13 of the target object 11. Consequently, a groove (laser-processed groove) 37 extending from the top surface 11a to the undersurface 11b of the target object 11 is formed along the planned dividing line 13. Then, when grooves 37 are formed along all of the planned dividing lines 13, the target object 11 is divided into a plurality of chips 25. Incidentally, in a case where it is difficult to form a groove 37 by one time of laser beam irradiation, the laser beam 130 may be applied along each planned dividing line 13 a plurality of times.

As described above, the target object 11 is divided into a plurality of chips 25 in the dividing step. The sheet 21 fixed to the target object 11 (plurality of chip 25) is thereafter expanded (expanding step). The expansion of the sheet 21 may be performed by using a dedicated apparatus such as the expanding apparatus 20 (FIG. 5A) described above, or may be performed manually by the worker. When the expanding step is performed, intervals between the plurality of chips 25 fixed to the sheet 21 are widened, and a certain space or more is secured between chips 25 adjacent to each other. Thus, collision between chips 25 at a time of subsequent transportation of the target object 11 does not occur easily, so that damage to the chips 25 is prevented.

As described above, in the processing step S2, the sheet 21 may be expanded after the target object 11 is divided. However, when the sheet 21 is expanded, slack occurs in the sheet 21 as in the case of applying an external force to the target object 11 (see FIG. 5B). Accordingly, after the processing step S2, as illustrated in FIG. 6, the light absorbing member 32 is brought into contact with the unfixed region 21a of the sheet 21 (light absorbing member disposing step S3), and thereafter the unfixed region 21a is heated and shrunk by making the light absorbing member 32 generate heat through irradiation of the light absorbing member 32 with the light 38 (shrinking step S4).

Thus, in the sheet processing method (chip manufacturing method) according to the present embodiment, the division of the target object 11 and the expansion of the sheet 21 are performed in the processing step S2, and thereafter the unfixed region 21a of the sheet 21 is heated and shrunk in the shrinking step S4. Slack occurring in the unfixed region 21a is thereby reduced or removed.

Details of the light absorbing member disposing step S3 and the shrinking step S4 are as described in the first embodiment. Incidentally, the slack in the sheet 21 in the processing step S2 may be suppressed in advance by performing the light absorbing member disposing step S3 and the shrinking step S4 in advance before the processing step S2 is performed.

Besides, structures, methods, and the like according to the present embodiment can be modified and implemented as appropriate without departing from the objective scope of the present invention. In addition, the present embodiment can be combined with the first embodiment as appropriate, and descriptions in the first embodiment can be incorporated as appropriate for items not described in the present embodiment.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A sheet processing method for processing a sheet fixed to a target object, the sheet processing method comprising:
preparing the target object to which the sheet is fixed;
bringing a light absorbing member configured to generate heat by absorbing light into contact with an unfixed region not fixed to the target object in the sheet; and
heating and shrinking the unfixed region by making the light absorbing member generate heat through irradiation of the light absorbing member with the light.

2. The sheet processing method according to claim 1, wherein
the sheet is fixed to an annular frame having an opening portion in which the target object is capable of being disposed, and
the unfixed region is an annular region exposed between the target object and the frame.

3. The sheet processing method according to claim 1, wherein
the target object is processed, and
the unfixed region in which slack occurs due to the processing of the target object is shrunk.

4. The sheet processing method according to claim 3, wherein
the processing of the target object is processing that, after forming division starting points in the target object along a planned dividing line, divides the target object along the planned dividing line by expanding the sheet.

5. The sheet processing method according to claim 3, wherein
the prepared target object has a recessed portion provided in a central portion of the target object and has an annular reinforcing portion provided in an outer circumferential portion of the target object, the reinforcing portion surrounding the recessed portion, the sheet being fixed to the recessed portion and the reinforcing portion, and
the processing of the target object is processing that separates the reinforcing portion from the target object.

6. A chip manufacturing method for manufacturing chips by dividing a target object to which a sheet is fixed, the chip manufacturing method comprising:
preparing the target object to which the sheet is fixed;
after forming division starting points in the target object along a planned dividing line, dividing the target object into a plurality of the chips along the planned dividing line by expanding the sheet;
bringing a light absorbing member configured to generate heat by absorbing light into contact with an unfixed region not fixed to the target object in the sheet; and
heating and shrinking the unfixed region by making the light absorbing member generate heat through irradiation of the light absorbing member with the light.

7. A chip manufacturing method for manufacturing chips by dividing a target object to which a sheet is fixed, the chip manufacturing method comprising:
preparing the target object to which the sheet is fixed;
after dividing the target object into a plurality of the chips along a planned dividing line, widening intervals between the plurality of chips by expanding the sheet;
bringing a light absorbing member configured to generate heat by absorbing light into contact with an unfixed region not fixed to the target object in the sheet; and
heating and shrinking the unfixed region by making the light absorbing member generate heat through irradiation of the light absorbing member with the light.

8. A substrate manufacturing method for manufacturing a substrate by processing a target object to which a sheet is fixed, the substrate manufacturing method comprising:
preparing the target object having a recessed portion provided in a central portion of the target object and having an annular reinforcing portion provided in an outer circumferential portion of the target object, the reinforcing portion surrounding the recessed portion, the sheet being fixed to the recessed portion and the reinforcing portion;
manufacturing the substrate by separating the reinforcing portion from the target object;
bringing a light absorbing member configured to generate heat by absorbing light into contact with an unfixed region not fixed to the target object in the sheet; and
heating and shrinking the unfixed region by making the light absorbing member generate heat through irradiation of the light absorbing member with the light.
